(19) United States
(12) Patent Application Publication
(10) Pub. No.: US 2004/0248405 A1
(43) Pub. Date: Dec. 9, 2004

(54) Method of and apparatus for manufacturing semiconductor device

(76) Inventors: Akira Fukunaga, Tokyo (JP); Manabu Tsujimura, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/856,800

(22) Filed: Jun. 1, 2004

(30) Foreign Application Priority Data
Jun. 2, 2003 (JP) 2003-156500
Jul. 25, 2003 (JP) 2003-201468

(51) Int. Cl. H01L 21/44; H01L 21/4763

(52) U.S. Cl. 438/637; 438/687; 438/631

(57) ABSTRACT

A damaged layer which is necessarily produced on the exposed surface of an interconnect by flattening of a surface of a substrate for forming interconnect according to a damascene process is restored, making it possible to manufacture semiconductor devices with a high yield. A semiconductor device is manufactured by preparing a substrate having an interconnect recess formed in an interlevel dielectric, depositing an interconnect material on the surface of the substrate to embed the interconnect material in the interconnect recess, removing the interconnect material excessively formed on the surface of the substrate to flatten the surface of the substrate, thereby forming an interconnect of the interconnect material, and restoring a damaged layer formed on the exposed surface of the interconnect.

### BACKGROUND OF THE INVENTION

1. Field of the Invention

The present invention relates to a method of and an apparatus for manufacturing a semiconductor device, and more particularly to a method of and an apparatus for manufacturing a semiconductor device by filling fine interconnect recesses such as interconnect trenches, contact holes, etc. previously formed in an interlevel dielectric deposited on a surface of a substrate, such as a semiconductor wafer or the like, with an interconnect material (conductive metal) such as aluminum, copper, silver, or their alloy, and thereafter removing an extra metal to flatten the surface of the substrate, thereby forming embedded interconnects on the surface of the substrate.

2. Description of the Related Art

There has been employed a damascene process for embedding an interconnect material (conductive metal) into interconnect trenches, contact holes, etc. as an interconnect forming process for manufacturing semiconductor devices. According to the damascene process, a barrier layer of TiN, TaN, WN, or the like for preventing an interconnect material from being diffused into an interlevel dielectric is formed by sputtering or CVD in interconnect recesses such as interconnect trenches, contact holes, etc. formed in an interlevel dielectric on a substrate, and then a metal such as aluminum, or more recently, a metal such as copper, silver, or the like is embedded in the interconnect recesses by sputtering, CVD, or plating. Thereafter, an extra metal and the barrier layer formed on the interlevel dielectric are removed by chemical mechanical polishing (CMP) so as to flatten a surface of the substrate. Thus, embedded interconnects are formed.

In a case of interconnects formed such a process, embedded interconnects have an exposed surfaces after flattening processing. When an additional embedded interconnect structure is formed on such a substrate, it is customary to form an insulating film such as of SiN, SiC, or the like on the entire surface of the substrate including the metal interconnects according to CVD or the like. However, such an insulating film is generally of a relatively high dielectric constant regardless of the present tendency toward lower dielectric constants of interlevel dielectric due to finer interconnects. For achieving lower dielectric constants and increasing the reliability of semiconductor devices based on design rules with respect to interconnect sizes of 0.1 μm or smaller, there has been proposed a process of selectively forming a protective film of cobalt, nickel, or their alloy on surfaces of interconnects by electroless plating to cover the surfaces of interconnects with the protective film for thereby protecting the interconnects.

FIGS. 1A through 1D of the accompanying drawings show successive steps of a process of forming copper interconnects in a semiconductor device. According to the illustrated process, as shown in FIG. 1A, an insulating film (interlevel dielectric) 2 such as an oxide film of SiO₂ or a Low-k material film is deposited on a conductive layer 1a on a semiconductor base 1 where semiconductor devices have been formed. Then, contact holes 3 and interconnect trenches 4 as fine interconnect recesses are formed in the insulating film 2 by a lithography/etching technique. A barrier layer 5 of TaN or the like is formed on exposed surfaces of the conductive layer la and insulating film 2, and then a seed layer 6 as a electric supply layer for electroplating is formed on the barrier layer 5 by sputtering or the like.

Then, as shown in FIG. 1B, copper plating is performed to fill the contact holes 3 and the interconnect trenches 4 with copper and, at the same time, deposit a copper film 7 on the barrier layer 5. Thereafter, the copper film 7, the seed layer 6, and the barrier layer 5 on the insulating film 2 are removed by chemical mechanical polishing (CMP) or the like, making the surface of the copper film 7 in the contact holes 3 and the interconnect trenches 4 lying substantially flush with the surface of the insulating film 2. As a result, as shown in FIG. 1C, interconnects (copper interconnects) 8 composed of the seed layer 6 and the copper film 7 are thus formed in the insulating film 2.

Then, as shown in FIG. 1D, the surface of the substrate W is subjected to electroless plating to selectively form a protective film 9 composed of a Co alloy, an Ni alloy, or the like on the surfaces of the copper interconnects 8, thereby covering the surfaces of the copper interconnects 8 with the protective film 9 to protect the copper interconnects 8.

### SUMMARY OF THE INVENTION

Heretofore, for flattening such interconnects, e.g., copper interconnects composed of copper as an interconnect material, it has been the customary practice to oxidize the surfaces of the interconnect material such as copper with an oxidizing agent such as hydrogen peroxide, ammonium persulfate, or the like or anode polarization, and thereafter to polish the oxidized interconnect material (oxide layer) with e.g., abrasive grain. On the exposed surfaces of the flattened copper interconnects, there remain damaged layers which have been chemically damaged by the oxidizing agent or the like or physically damaged by the polishing agent or the like. Though some attempts are made to minimize such damage in the flattening process, it is not possible to avoid the damaged layers that remain left on the surfaces of interconnects either chemically or physically because the oxide layer is formed and the surface is flattened by physically removing the oxide layer. As finer interconnects are formed, the damaged layers that remain on the surfaces of exposed interconnects tends to adversely affect the reliability of semiconductor devices that are produced.

The damaged layers formed chemically or physically on the exposed surfaces of interconnects during the flattening process maybe restored by a dry process or a wet process. If a dry process such as DVD or the like is carried out after the flattening process, then it is preferable to restore the damaged layer with a dry process such as a plasma process to match such a subsequent process. If a process subsequent to the flattening process is a plating process, spin coating process, or the like that is carried out under normal pressure, on the other hand, then a wet process such as wet etching may be employed to restore the damaged layer for better matching the subsequent process.

For flattening copper interconnects composed of copper as an interconnect material according to CMP or the like, a copper film formed in regions other than the embedded regions is removed with a slurry under polishing conditions such that the polishing rate for the copper is higher than a barrier material, and then the barrier material formed in regions other than the embedded regions is removed with a slurry under polishing conditions such that the polishing rate for the barrier material is higher than the copper, thereby forming embedded interconnects. In a state where the copper as the interconnect material and the barrier material coexist on the surface of the substrate, then the portions of the copper interconnects which have boundaries held in contact with the barrier material are corroded due to a potential difference that is developed between the copper and the barrier material during the polishing process, post-cleaning process, or the like, tending to cause local corrosion wastage (also referred to as spike). Such corrosion wastage is responsible for a reduction in the reliability of the semiconductor device due to an increase in the interconnect resistance, poor adhesion between the interconnect material and a film formed thereon, etc.

Relatively large corrosion wastage in the flattening process has already been overcome by selecting an appropriate slurry and improving cleaning conditions, for example. Smaller corrosion wastage (spike), on the other hand, has not posed significant problems as it is hidden by excessive polishing of the copper film owing to dishing or erosion. However, as the polishing process has been improved to reduce excessive polishing in view of finer design rules, e.g., interconnect sizes of less than 0.1 μm, the corrosion wastage that has been concealed has begun to surface, tending to affect the reliability of semiconductor devices. When a protective film (cap) composed of a metal having a high melting point is selectively deposited by electroless plating on the surfaces of interconnects to protect the interconnects, the corrosion wastage may further be promoted depending on processing conditions of the electroless plating.

Though the effect of corrosion wastage may be reduced by improving polishing conditions, cleaning conditions, or the electroless plating process for forming a protective film, it is difficult to completely eliminate the effect of corrosion wastage.

The present invention has been made in view of the above drawbacks. It is therefore a first object of the present invention to provide a method of and an apparatus for manufacturing a semiconductor device with a high yield by eliminating the effect of a damaged layer which is necessarily produced on the exposed surface of an interconnect by flattening the surface of the substrate for forming the interconnect according to the damascene process.

A second object of the present invention is to provide a method of and an apparatus for manufacturing a semiconductor device with a high yield by restoring corrosion wastage of an interconnect material which occurs on the exposed surface of an interconnect in a flattening process when an embedded interconnect is formed according to the damascene process.

To achieve the above object, there is provided in accordance with the present invention a method of manufacturing a semiconductor device, comprising: preparing a substrate having a interconnect recess formed in an interlevel dielectric on a surface of the substrate; depositing an interconnect material on the surface of the substrate to embed the interconnect material in the interconnect recess; removing the interconnect material excessively formed on the surface of the substrate to flatten the surface of the substrate, thereby forming an interconnect of the interconnect material; and restoring a damaged layer formed on the exposed surface of the interconnect.

By thus restoring the damaged layer that is formed on the surface of the interconnect upon flattening thereof, a highly reliable semiconductor device can be manufactured.

The damaged layer may be restored by a dry process.

If a process subsequent to the flattening process of the surface of the substrate to form the interconnect is a dry process such as CVD or the like, then the damaged layer is preferably restored by a dry process for better matching the subsequent process. The dry process for restoring the damaged layer may be a plasma process, for example. If the substrate is processed by the plasma process in a reducing atmosphere such as of hydrogen, ammonia, or the like, then the damaged layer can be restored to remove damages including a chemical damage without damaging the interconnect. The same process can be performed by processing the heated substrate with an organic vapor for reducing a metal oxide, e.g., an organic acid such as acetic acid, formic acid, alcohol such as methanol, ethanol, or aldehyde such as formaldehyde, acetic aldehyde. After the damaged layer has been restored by the dry process, the substrate may be processed in a next process comprising a wet process.

The damaged layer may be restored by a wet process.

If a process subsequent to the flattening process of the surface of the substrate to form the interconnect is a plating process, a spin coating process, or the like that is performed under normal pressure, then the damaged layer is preferably restored by a wet process for better matching the subsequent process. The wet process for restoring the damaged layer may be a chemical process such as an etching process using a chemical liquid or a chemical action such as a reducing action, a process based on a mechanical action such as a polishing action, or a combination of chemical and mechanical actions. If the damaged layer is restored by a wet process, then since various actions may be combined for use as the wet process, there is preferably a possibility of selecting a desired process depending on the object to be restored. After the damaged layer has been restored by the wet process, the substrate may be processed in a next process comprising a dry process.

The damaged layer is preferably restored by the wet process, following the removing the interconnect material excessively formed on the surface of the substrate to flatten the surface of the substrate.

If the damaged layer formed on the surface of the interconnect is restored by a wet process, then since the surface of the substrate is generally flattened by a wet process, it is efficient to restore the damaged layer successively after the surface of the substrate is flattened. The damaged layer may be restored by a wet process by processing the substrate using any of various units of a polishing apparatus, e.g., processing the substrate with a chemical liquid in a cleaning unit which is used to clean the substrate after the substrate is flattened (polished), or supplying a restorative slurry or chemical liquid after the substrate is polished in a polishing unit used to flatten the substrate.

The damaged layer may be restored by the wet process, following the removing the interconnect material excessively formed on the surface of the substrate to flatten the surface of the substrate and drying the substrate.

If the processing time of the flattening process and the processing time of the restoring process are widely different from each other, then the damaged layer is preferably restored after the flattening process has been completed for the purpose of increasing the throughput. In this case, it is preferable to clean and dry the flattened substrate.

The damaged layer may be dissolved away in a chemical liquid.

The damaged layer that is formed on the exposed surface of the interconnect in the flattening process includes a mixture of a layer that is chemically damaged by the oxidizing agent and a layer that is physically damaged by the polishing agent. Either of these layers is bonded more weakly to the substrate than the bulk metal. Therefore, the rates at which the metal (interconnect) and the oxide (damaged layer) are dissolved by chemical liquids are compared with each other, for example, and a chemical liquid for dissolving the damaged layer faster than the interconnect is selected and applied to the surface of the substrate to remove only the damaged layer which is chiefly composed of the oxide layer without causing damage to the interconnect. If the interconnect is made of copper or a copper alloy, then the desired effect can be achieved by using a non-oxide acid such as hydrochloric acid, sulfuric acid, hydrofluoric acid, or the like as the chemical liquid. Since the interconnect may possibly be oxidized by dissolved oxygen in the chemical liquid and portions thereof which are not damaged may possibly be dissolved by the dissolved oxygen, the amount of dissolved oxygen in the chemical liquid that is supplied may be reduced and the atmosphere may be controlled to eliminate the effect of oxygen in the atmosphere. The amount of dissolved oxygen in the chemical liquid may be controlled by bubbling the chemical liquid with nitrogen. The atmosphere may be controlled by introducing an inactive gas such as a nitrogen gas during the damage restoring process.

The chemical liquid is preferably ejected to the surface of the substrate that is held with the surface facing downwardly.

The chemical liquid may be supplied to the surface of the substrate as by dipping the substrate in the chemical liquid, supplying the chemical liquid to the surface (upper surface) of the substrate while the substrate is being held with its surface facing upwardly, or spraying the chemical liquid from e.g., a spray to the surface (lower surface) of the substrate while the substrate is being held with its surface facing downwardly with a spray. As described above, portions of the interconnect which are not damaged may possibly be dissolved by the oxygen in the atmosphere, depending on the chemical liquid used to dissolve the damaged layer. In this case, the chemical liquid needs to be removed from the surface of the substrate immediately after the damage restoring process. The substrate can be rinsed more easily and the applied chemical liquid can be removed with greater ease in the process of spraying the chemical liquid from e.g., a spray to the surface (lower surface) of the substrate while the substrate is being held with its surface facing downwardly, than the process of dipping the substrate in the chemical liquid or the process of supplying the chemical liquid to the surface (upper surface) of the substrate while the substrate is being held with its surface facing upwardly. Alternatively, the environment in which the spray is applied to the substrate and/or the environment in which the substrate is rinsed may be filled with an inactive gas to eliminate the effect of the oxygen in the atmosphere during the damage restoring process.

If a process subsequent to the restoration of the damaged layer is an electroless plating process for forming a protective film while the substrate is being held with its surface facing downwardly, then the damaged layer is restored while the substrate is being held with its surface facing downwardly. In this manner, the protective layer can subsequently be formed on the substrate by electroless plating without changing the orientation of the substrate.

The damaged layer may be restored by being reduced with a solution containing a reducing agent.

If the damaged layer is primarily damaged chemically by an oxidizing agent or the like, then it is appropriate to reduce the damaged layer into a metal state with a reducing agent. The reducing agent needs to be a material capable of donating electrons to at least the interconnect material. If the interconnect material is copper, for example, then the reducing agent may be formaldehyde, dimethylamineborane, hydrazine, or the like.

The solution containing the reducing agent is preferably ejected to the surface of the substrate that is held with the surface facing downwardly.

The surface of the substrate may be polished in the presence of a solution containing a reducing agent.

When the chemically damaged layer is restored by the reducing agent, the surface of the substrate is also polished to uniformly process the entire surface of the substrate.

The surface of the substrate may be polished using a slurry containing at least a reducing agent and abrasive grain.

If the chemically damaged layer is also slightly physically damaged, then the substrate maybe polished by a slurry comprising a reducing agent and abrasive gain to restore the damaged layer which is both chemically and physically damaged.

The surface of the substrate is polished, for example, by moving the substrate and a polishing surface relatively to each other while pressing the surface of the substrate that is held with the surface facing downwardly against the polishing surface.

As described above, if a process subsequent to the restoration of the damaged layer is an electroless plating process for forming a protective film while the substrate is being held with its surface facing downwardly, then the damaged layer is restored while the substrate is being held with its surface facing downwardly. In this manner, the protective layer can subsequently be formed on the substrate by electroless plating without changing the orientation of the substrate.

The interconnect formed on the surface of the substrate may be subjected to cathode polarization, and the damaged layer may be restored by being reduced electrochemically.

If the damaged layer is reduced into a metal state by a reducing solution, then the substrate needs to be rinsed subsequently. However, the interconnect may be damaged while the substrate is being rinsed. Since the damaged layer (oxide layer) is restored by an electrochemical reducing action by subjecting the interconnect on the surface of the substrate to cathode polarization in ultrapure water or the like, the substrate does not need to be rinsed, and hence is not damaged in the rinsing process. If the interconnect material is copper, then the damaged layer (oxide layer) immediately after it is produced can be reduced to copper when subjected to cathode polarization at a potential of about 0.4 V with respect to the standard hydrogen electrode potential.

A mesh-like cathode may be held in contact with the surface of the substrate to subject the interconnect to cathode polarization.

The embedded interconnect formed on the surface of the substrate may be subjected to cathode polarization most easily by bringing the mesh-like cathode into contact with the surface of the substrate. Even if a hydrogen gas is generated, the cathode which is of a mesh structure allows the hydrogen gas to be easily removed, making it possible to perform the reducing reaction smoothly. The electrode material is preferably a material having a high hydrogen over voltage, such as copper, lead, zinc, or the like in order that the cathode current will not be used to generate hydrogen.

The interconnect material may comprise copper, a copper alloy, silver, or a silver alloy.

Various materials are available for use as the interconnect material. Semiconductor devices which need to take into account the damaged layer formed on the interconnect are generally of a highly integrated structure. Metal materials such as copper, a copper alloy, silver, a silver alloy, etc. can be used as the interconnect material in such highly integrated semiconductor devices.

The interconnect material is deposited by plating, for example.

While the interconnect material may be embedded by a dry process such as CVD or the like, the plating process is most suitable from the standpoint of productivity.

The removing the interconnect material excessively formed on the surface of the substrate to flatten the surface of the substrate is performed by chemical mechanical polishing, electrochemical polishing, composite electrolytic polishing, or a combination thereof.

One typical flattening process is a chemical mechanical polishing (CMP) process. Other electrochemical polishing process or composite electrolytic polishing process may be employed, or these processes may be combined with each other for making the entire process efficient.

The damaged layer is preferably restored in a light-shielded environment.

When the surface of interconnect is exposed on the surface of the substrate upon flattening thereof, it may possibly be corroded by illuminating light in a cleaning room wherein the substrate is processed. Interconnect is prevented from suffering light-induced corrosion by restoring the damaged layer in a light-shielded environment.

It is preferable to selectively form a protective film on the exposed surface of the interconnect on the surface of the substrate after the damaged layer is restored.

The exposed surface of the interconnect whose damaged layer has been restored is unstable and is susceptible to oxidization. After the damaged layer of the interconnect is restored, a protective film is selectively formed on the surface of the interconnect without a time interval, thus preventing the interconnect from being oxidized.

It is preferred that the protective film is formed by electroless plating, and the substrate is dried after the protective film is formed by electroless plating.

Although the protective film may also be formed by a dry process such as CVD or the like, it is preferably deposited by electroless plating in view of the need to form the protective film without a time interval. The protective film should be made of nickel, cobalt, or an alloy thereof for optical stability.

According to the present invention, there is also provided an apparatus for manufacturing a semiconductor device, comprising: a plating unit for depositing an interconnect material on a surface of a substrate having an interconnect recess formed in an interlevel dielectric to embed the interconnect material in the interconnect recess; a polishing unit for removing the interconnect material excessively formed on the surface of the substrate to flatten the surface of the substrate, thereby forming an interconnect of the interconnect material; and a damaged layer restoring unit for restoring a damaged layer formed on the exposed surface of the interconnect.

The damaged layer restoring unit has a substrate holder for holding the substrate with the surface facing downwardly, and a liquid ejection nozzle for ejecting a liquid toward the surface of the substrate that is held by the substrate holder. The liquid comprises a chemical liquid for dissolving the damaged layer or a solution containing a reducing agent.

The damaged layer restoring unit has a top ring vertically movable for holding the substrate with the surface facing downwardly, a polishing table having an upper surface as a polishing surface, a liquid supply nozzle for supplying a liquid to the polishing surface of the polishing table, and a relatively moving mechanism for moving the top ring and the polishing table relatively to each other. The liquid comprises a solution containing a reducing agent or a slurry containing a reducing agent and abrasive grain.

The damaged layer restoring unit has a mesh-like cathode for contacting the surface of the substrate to subject the interconnect to cathode polarization, an anode disposed in confronting relation to the surface of the substrate, and a liquid filled between the surface of the substrate and the anode.

Preferably, the apparatus further includes an electroless plating unit for selectively forming a protective film on the exposed surface of the interconnect.

According to the present invention, there is also provided a method of manufacturing a semiconductor device, comprising: preparing a substrate having an interconnect recess formed in an interlevel dielectric on a surface of the substrate; depositing an interconnect material on the surface of the substrate to embed the interconnect material in the interconnect recess; removing the interconnect material excessively formed on the surface of the substrate to flatten the surface of the substrate, thereby forming an interconnect of said interconnect material; and restoring a wastage portion formed on the exposed surface of the interconnect when the surface of the substrate has been flattened.

Since the wastage portion formed on the exposed surface of the interconnect by the flattening process for forming the interconnect, embedded interconnect less liable to suffer defects is formed, allowing highly reliable semiconductor devices to be manufactured.

Preferably, the interconnect recess has a minimum dimension of up to 0.1 μm.

In a semiconductor device generation where design rules with respect to interconnect sizes of 0.1 μm or smaller are applied, then the excessive polishing of a copper film due to dishing and erosion is reduced because of an improved flattening process, and the effect of wastage portion is not negligible. In the process of depositing the protective layer (cap) according to electroless plating in such a semiconductor device generation or subsequent generation, the wastage portion may be promoted. For manufacturing highly reliable semiconductor devices in a generation where the minimum dimension of interconnect recess is 0.1 μm or less, therefore, the restoration of the wastage portion is essential.

The wastage portion formed on the exposed surface of the interconnect is, for example, restored by electroless plating or electroplating.

A process of restoring the wastage portion on the exposed surface of the interconnect by a flattening process such as a polishing process or a post-cleaning process needs to deposit the interconnect material mainly in the wastage portion only. The electroless plating or electroplating process can meet such a need. These processes are a wet process to be performed in a solution, it better matches the polishing process or the post-cleaning process if it follows these processes in the same apparatus.

Electroless plating is able to precipitate the interconnect material selectively on the surface of the interconnect only to restore the wastage portion. According to the electroplating, an additive for good embeddability of the plating solution may be selected to precipitate the interconnect material from the wastage portion to restore the wastage portion. The electroplating needs to subject the interconnect to cathode polarization, and contacts may be provided on pad regions on respective chips on the substrate to supply an electric current to the interconnect.

In this case, the surface of the interconnect other than the wastage portion may be rubbed by a polishing cloth, suppressing the precipitation of a plated film in regions other than the regions to be restored for better selectivity.

Preferably, at least a portion of a peripheral region of the exposed surface of the interconnect is etched away before the wastage portion is restored.

Before the wastage portion is restored, at least a portion of a surrounding region of the wastage portion of the interconnect material is etched away to make blunt the shape of the wastage portion. The wastage portion thus made blunt in shape allows itself to be restored with ease.

It is preferred that the substrate is heat-treated after the wastage portion is restored.

When the substrate is thus heat-treated, the adhesion between an un-restored region and a restored region is improved, and the film quality of the interconnect is increased.

The interconnect material is deposited, for example, by sputtering, CVD, plating, or a combination thereof.

For embedding the interconnect material in the interconnect recess formed in the interlevel dielectric, a barrier layer is formed by sputtering, and then the interconnect material is embedded by sputtering, CVD, plating, or a combination thereof. One of these processes is employed depending on the type of the interconnect material and the design rules.

The interconnect material may be deposited by a process including a plating process having at least two plating conditions changed.

For embedding the interconnect material in the interconnect recess after the barrier layer is formed, at least two plating conditions are changed to embed the interconnect material, thereby interconnect material can be embedded reliably. For example, if the interconnect material is to be embedded in the interconnect recess with the barrier layer formed therein directly according to a plating process, an electric supply layer is first formed by electroless plating, and then the interconnect material is embedded by electroplating using the electric supply layer as a seed layer. Alternatively, an electric supply layer is formed by electroplating using a high-resistance plating solution, and then the interconnect material is embedded by electroplating using a low-resistance plating solution. In this manner, the interconnect material may be embedded according to different plating processes using different plating solutions. Alternatively, if a electric supply layer is formed on the barrier layer by sputtering or CVD, and the interconnect material is embedded by electroplating with the same plating solution using the electric supply layer as a seed layer, then the interconnect material is initially embedded in regions of smaller dimensions with a lower current density, and after the interconnect material is embedded in the regions of smaller dimensions, the current density is increased to embed the interconnect material in regions of larger dimensions in a short period of time. In this manner, the interconnect material may be embedded under different current conditions. At any rate, it is preferable to embed the interconnect material under a plurality of selected conditions according to the plating process.

The interconnect material may comprise aluminum, copper, or silver, or an alloy thereof.

Aluminum, copper, silver, or an alloy thereof may be used as the interconnect material. In particular, the interconnect material used according to design rules for a semiconductor device generation where the interconnect size is 0.1 μm or less maybe copper, silver, or an alloy thereof. At present, however, copper is prevalent.

The interconnect material may be flattened by chemical mechanical polishing, composite electrolytic polishing, electrolytic polishing, or a combination thereof.

Processes of flattening the interconnect material include a chemical mechanical polishing process which is a combination of oxidization using a chemical oxidizing agent and physical removal using abrasive grain, a composite electrolytic polishing process which is a combination of electrolytic anodic oxidization and physical removal using abrasive grain, or an electrolytic polishing process which is a combination of electrolytic anodic oxidization and chemical action of a chemical liquid or the like. According to the chemical mechanical polishing process, a copper film in regions other than embedded regions is removed with a slurry under polishing conditions such that the polishing rate for the copper is higher than a barrier material, for example, and then the barrier layer formed in regions other than the embedded regions is removed with a slurry under polishing conditions such that the polishing rate for the barrier material is higher than the copper. In this manner, the substrate is polished in a plurality of stages of polishing conditions. Alternatively, the embedded interconnect may be formed by combining polishing processes such that after the highly conductive copper is polished away by the composite electrolytic polishing process or the electrolytic polishing process, the barrier layer is chemically mechanically polished to form the embedded interconnect with a slurry under polishing conditions such that the polishing rate for the barrier material is higher than the copper. The chemical mechanical polishing process includes a process using fixed abrasive grain or a process using no abrasive grain. The flattening process may be followed by a process of restoring the wastage portion that is formed in the flattening process.

It is preferable to selectively form a protective film on the exposed surface of the interconnect by electroless plating, after the wastage portion formed on the exposed surface of the interconnect is restored.

When a protective film (cap) composed of a metal having a high melting point is selectively formed by electroless plating on the surface of interconnect to protect the interconnect, the wastage portion (spike) may further be promoted in a pre-plating process. If electroless plating (cap plating) is performed without restoring the wastage portion, no plated film may be deposited on the wastage portion, possibly forming voids in the interconnect. After restoring the wastage portion to make the interconnect free of defects, electroless plating is performed to form the protective film (cap) on the exposed surface of the interconnect while preventing voids from being formed in the interconnect.

Preferably, the protective film is formed so as to have a surface thereof lying flush with a surface of the interlevel dielectric.

By thus making the surfaces flatter, it is possible to perform easily a subsequent process of forming an insulating film, and forming vias and trenches through application of a resist layer and exposure to light, and the like.

According to the present invention, there is further provided an apparatus for manufacturing a semiconductor device, comprising: a film deposition unit for depositing an interconnect material on a surface of a substrate having an interconnect recess formed in an interlevel dielectric to embed the interconnect material in the interconnect recess; a polishing unit for removing the interconnect material excessively formed on the surface of the substrate to flatten the surface of the substrate, thereby forming an interconnect of the interconnect material; and a restoring unit for restoring a wastage portion formed on the exposed surface of the interconnect when the surface of the substrate has been flattened by the polishing unit.

The film deposition unit may comprise an electroplating unit, an electroless plating unit, or a combination thereof.

The restoring unit may comprise an electroplating unit or an electroless plating unit.

Preferably, the apparatus further includes an electroless plating unit for selectively forming a protective film on the exposed surface of the interconnect which is restored by the restoring unit.

Preferably, the apparatus further includes an etching unit for etching away at least a portion of a peripheral region of the exposed surface of the interconnect before the wastage portion is restored by the restoring unit.

Preferably, the apparatus further includes a heat-treating unit for heat-treating the substrate in which the wastage portion has been restored by the restoring unit.

The above and other objects, features, and advantages of the present invention will become apparent from the following description when taken in conjunction with the accompanying drawings which illustrate a preferred embodiment of the present invention by way of example.

### BRIEF DESCRIPTION OF THE DRAWINGS

FIGS. 1A through 1D are fragmentary cross-sectional views showing successive steps of a process of forming a copper interconnect in a semiconductor device;

FIG. 2 is a plan view of a semiconductor device manufacturing apparatus according to an embodiment of the present invention;

FIG. 3 is a flowchart of a processing sequence of the semiconductor device manufacturing apparatus shown in FIG. 2;

FIG. 4 is a cross-sectional view of an example of a damaged layer restoration unit of the semiconductor device manufacturing apparatus shown in FIG. 2;

FIG. 5 is a cross-sectional view of another example of a damaged layer restoration unit of the semiconductor device manufacturing apparatus shown in FIG. 2;

FIG. 6 is a cross-sectional view of still another example of a damaged layer restoration unit of the semiconductor device manufacturing apparatus shown in FIG. 2;

FIG. 7 is a plan view of a semiconductor device manufacturing apparatus according to another embodiment of the present invention;

FIG. 8 is a flowchart of a processing sequence of the semiconductor device manufacturing apparatus shown in FIG. 7;

FIGS. 9A through 9D are fragmentary cross-sectional views showing successive steps of a process of recovering corrosion wastage portion of a substrate and forming a protective film;

FIG. 10 is a fragmentary cross-sectional view showing another process of recovering corrosion wastage portion of a substrate;

FIGS. 11A and 11B are fragmentary cross-sectional views showing successive steps of another process of recovering corrosion wastage portion of a substrate; and

FIGS. 12A through 12C are fragmentary cross-sectional views showing successive steps of still another process of recovering corrosion wastage portion of a substrate.

### DETAILED DESCRIPTION OF THE PREFERRED EMBODIMENTS

Preferred embodiments of the present invention will be described in detail below. In the embodiments described below, the present invention is applied to a semiconductor device manufacturing apparatus which embeds copper as an interconnect material in fine interconnect recesses defined in a surface of a substrate, such as a semiconductor wafer or the like, to form interconnects composed of a copper film. However, the present invention is also applicable to semiconductor device manufacturing apparatus which employs interconnect materials other than copper.

FIG. 2 shows in plan a semiconductor device manufacturing apparatus according to an embodiment of the present invention. As shown in FIG. 2, the semiconductor device manufacturing apparatus has a rectangular housing 12 to which transport boxes 10 such as a SMIF box for housing a number of substrates such as semiconductor wafers therein are detachably mounted. The housing 12 houses therein a loading/unloading station 14 and a movable transport robot 16 for transferring substrates to and from the loading/unloading station 14. The housing 12 also houses therein an electroplating unit 18 as a film deposition unit for embedding, a cleaning/drying unit 20, a bevel etching/reverse side cleaning unit 22, and a film thickness measuring unit 24, which are arrayed in line on one side of the transport robot 16, and also houses therein a heat-treating (annealing) unit 26, a pretreatment unit 28, an electroless plating unit 30 (cap plating unit) for forming a protective film, a damaged layer recovering unit 32, and a polishing unit 34, which are arrayed in line on the other side of the transport robot 16.

The housing 12 is shielded from light to allow various processes to be performed in the housing 12 against exposure to light, i.e., while preventing interconnects on substrates in the housing 12 from being exposed to illuminating light or the like. Since no light is applied to interconnects on substrates in the housing 12, light is prevented from irradiating interconnects of copper, for example, and hence a light-induced potential difference is prevented from being developed on such interconnects, thus preventing the interconnects from being corroded by such a light-induced potential difference.

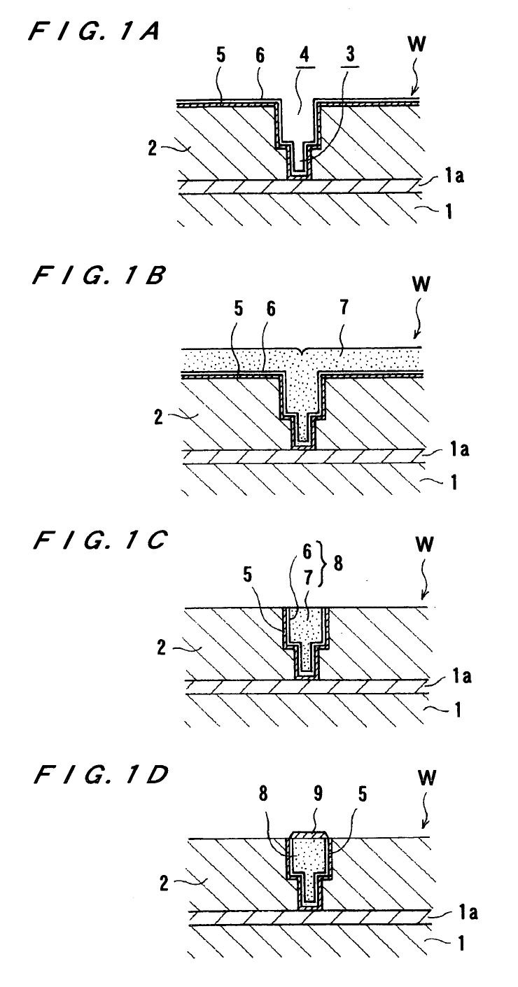

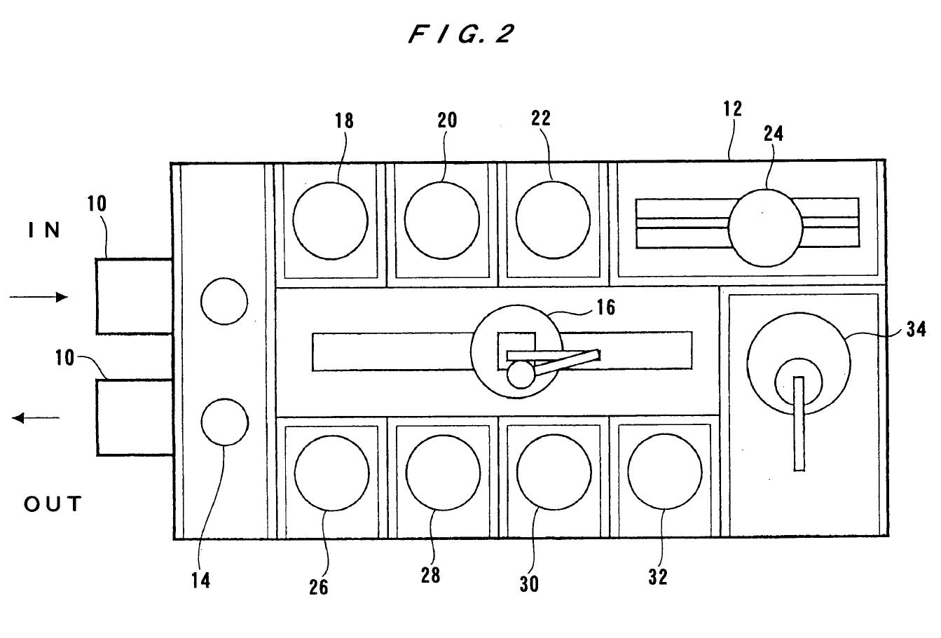

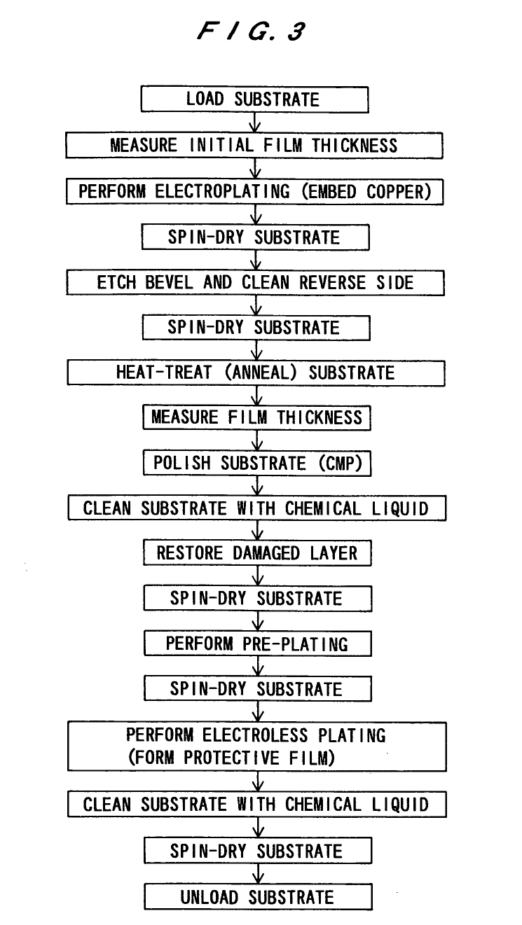

A successive steps of a process of forming copper interconnects on a substrate W with a seed layer 6 formed on its surface shown in FIGS. 1A through 1D, using the semiconductor device manufacturing apparatus shown in FIG. 2, will be described below with reference to FIG. 3.

First, a substrate W with a seed layer 6 formed on its surface is taken one by one from one of the transport boxes 10 into the loading/unloading station 14. The substrate W introduced into the loading/unloading station 14 is then transported by the transport robot 16 to the film thickness measuring unit 24, which measures an initial film thickness, i.e., the film thickness of the seed layer 6. Thereafter, the substrate W is reversed, if necessary, and transported to the electroplating unit (film deposition unit) 18. In the electroplating unit 18, a copper film 7 is deposited on the surface of the substrate W to embed copper, as shown in FIG. 1B.

In the present embodiment, the single electroplating unit 18 serves as a film deposition unit. Using the same plating solution, electroplating in the electroplating unit 18 is initially effected to embed copper in regions of smaller dimensions with a lower current density. After the copper is embedded in the regions of smaller dimensions, electroplating in the electroplating unit 18 is effected with an increased current density to embed copper in regions of larger dimensions in a short period of time.

The film deposition unit may comprise a combination of an electroplating unit and an electroless plating unit. Alternatively, the film deposition unit may comprise a desired combination of a plating unit, a sputtering unit, and a CVD unit. According to the latter combination, a substrate with no seed layer formed on its surface is introduced into the film deposition unit, and a seed layer may be formed on the surface of the substrate by the electroless plating unit, the sputtering unit, or the CVD unit.

The substrate with the copper film 7 deposited thereon is then transported by the transport robot 16 to the cleaning/drying unit 20, which cleans the substrate W with pure water and then spin-dries the substrate W. If the electroplating unit 18 has a spin-drying function, then the electroplating unit 18 spin-dries (dewaters) the substrate W. The dried substrate W is transported to the bevel etching/reverse side cleaning unit 22 by the transport robot 16.

The bevel etching/reverse side cleaning unit 22 etches away unnecessary copper attached to the bevel (edge) portion of the substrate W and at the same time cleans the reverse side of the substrate W with pure water or the like. Thereafter, as described above, the substrate W is transported by the transport robot 16 to the cleaning/drying unit 20, which cleans the substrate W with pure water and then spin-dries the substrate W. If the bevel etching/reverse side cleaning unit 22 has a spin-drying function, then the bevel etching/reverse side cleaning unit 22 spin-dries the substrate W. The dried substrate W is transported to the heat-treating unit 26 by the transport robot 16.

The heat-treating unit 26 heat-treats (anneals) the substrate W. The heat-treated substrate W is transported by the transport robot 16 to the film thickness measuring unit 24, which measures the film thickness of copper and determines the film thickness of the copper film 7 (see FIG. 1B) based on the difference between the measured film thickness and the initial film thickness referred to above. Based on the determined film thickness of the copper film 7, the period of time required for plating the substrate W at a next time is adjusted, for example. If the determined film thickness of the copper film 7 is not enough, then copper is additionally deposited on the substrate W by plating again. After the film thickness of the copper film 7 is measured, the substrate W is transported to the polishing unit 34 by the transport robot 16.

The polishing unit 34 polishes away an unnecessary copper film 7, the seed layer 6, and the barrier layer 5 deposited on the surface of the substrate W, as shown in FIG. 1C, to flatten the surface of the substrate W. As shown in FIG. 1C, interconnects (copper interconnects) 8 composed of the seed layer 6 and the copper film 7 are then formed in the insulating film (interlevel dielectric) 2. At this time, the film thickness and the finished state of the substrate are inspected with a monitor, for example. When the monitor detects an end point of the polishing process, the polishing unit 34 finishes the polishing process. The polished substrate W is transported by the transport robot 16 to the cleaning/drying unit 20, which cleans the surface of the substrate W with a chemical liquid and thereafter cleans (rinses) the substrate W with pure water. The rinsed substrate W is transported to the damaged layer restoring unit 32 by the transport robot 16.

In the present embodiment, the surface of the substrate W is flattened by a chemical mechanical polishing (CMP) process that is a combination of oxidization using a chemical oxidizing agent and physical removal using abrasive grain. Specifically, the copper film 7 in regions other than embedded regions is removed with a slurry under polishing conditions such that the polishing rate for the copper is higher than a barrier material, and then the barrier layer 5 formed in regions other than the embedded regions is removed with a slurry under polishing conditions such that the polishing rate for the barrier material is higher than the copper. In this manner, the substrate W is polished in a plurality of stages of polishing conditions. The chemical mechanical polishing process includes a process using fixed abrasive grain or a process using no abrasive grain.

The surface of the substrate W may be polished according to a composite electrolytic polishing process which is a combination of electrolytic anodic oxidization and physical removal using abrasive grain, an electrolytic polishing process which is a combination of electrolytic anodic oxidization and chemical action of a chemical liquid, or a combination of these processes, rather than the chemical mechanical polishing process.

The damaged layer restoring unit 32 restores damaged layers formed (remaining) on the exposed surfaces of the interconnects (copper interconnects) 8 by dissolving away the damaged layers with a chemical liquid or reducing the damaged layers into a metal state (copper).

The polishing unit 34 oxidizes the surface of the interconnect material such as copper or the like with an oxidizing agent such as hydrogen peroxide, ammonium persulfate, or the like or anode polarization, and thereafter polishes the oxidized interconnect material (oxide layer) with abrasive grain or the like. On the exposed surfaces of the flattened copper interconnects 8, there remain damaged layers which have been chemically damaged by the oxidizing agent or the like or physically damaged by the polishing agent or the like. The damaged layers that remain left on the surfaces of interconnects tend to adversely affect the reliability of semiconductor devices that are produced. Highly reliable semiconductor devices can be manufactured by restoring the damaged layers to remove the adverse effect that the damaged layers have on the reliability of the semiconductor devices.

If a process subsequent to the flattening of the surface of the substrate to form the interconnects is a dry process such as CVD or the like, then the damaged layers are preferably restored by a dry process for better matching the subsequent process. The dry process for restoring the damaged layers may be a plasma process, for example. Particularly, if the substrate is processed by the plasma process in a reducing atmosphere such as of hydrogen, ammonia, or the like, then the damaged layers can be restored to remove damages including a chemical damage without damaging the interconnects. After the damaged layers have been restored by the dry process, the substrate may be processed in a next process comprising a wet process.

If a process subsequent to the flattening of the surface of the substrate to form the interconnects is a plating process, a spin coating process, or the like that is performed under normal pressure, as in this embodiment, then the damaged layers are preferably restored by a wet process for better matching the subsequent process. The wet process for restoring the damaged layers may be a chemical process such as an etching process using a chemical liquid or a chemical action such as a reducing action, a process based on a mechanical action such as a polishing action, or a combination of chemical and mechanical actions. If the damaged layers are restored with a wet process, then since various actions may be combined for use as the wet process, there is preferably a possibility of selecting a desired process depending on the object to be restored. After the damaged layers have been restored by the wet process, the substrate may be processed in a next process comprising a dry process.

If the processing time of the flattening process and the processing time of the restoring process are widely different from each other, then the damaged layers are preferably restored after the flattening process has been completed for the purpose of increasing the throughput. In this case, it is preferable to clean and dry the flattened substrate.

Then, the substrate with the damaged layers being restored is transported by the transport robot 16 to the cleaning/drying unit 20, which cleans the substrate W with pure water, if necessary, and spin-dries the substrate W. If the damaged layer restoring unit 32 has a spin-drying function, then the damaged layer restoring unit 32 spin-dries (removes the liquid from) the substrate W.

The dried substrate W is then transported by the transport robot 16 to the pretreatment unit 28, which carries out a pre-plating process, which is at least one of a process of imparting a Pd catalyst to the surface of the substrate W and a process of removing an oxidized film from the exposed surface of the substrate W, for example. The pre-plated substrate W is then transported by the transport robot 16 to the cleaning/drying unit 20, which cleans the substrate W with pure water and then spin-dries the substrate W. Alternatively, if the pretreatment unit 28 has a spin-drying function, then the pretreatment unit 28 spin-dries (dewaters) the substrate W. The dried substrate W is transported to the electroless plating unit 30 (cap plating unit) for forming a protective film by the transport robot 16.

The electroless plating unit 30 performs electroless Co—W—P plating on the exposed surfaces of the interconnects 8 to selectively form a protective film (plated film) 9 composed of a Co—W—P alloy film on the exposed surfaces of the interconnects 8, thereby protecting the interconnects 8, as shown in FIG. 1D. The protective film 9 generally has a film thickness ranging from 0.1 to 500 nm, preferably from 1 to 200 nm, and more preferably from 10 to 100 nm. During the electroless plating, the film thickness of the protective film 9 is monitored. When the monitored film thickness reaches a predetermined value, i.e., when an end point of the film thickness is detected, the electroless plating unit 30 finishes the electroless plating process.

The substrate W is thereafter transported by the transport robot 16 to the cleaning/drying unit 20, which cleans the surface of the substrate W with a chemical liquid, cleans (rinses) the surface of the substrate W with pure water, and thereafter spin-dries the substrates W by rotating the substrate W at a high speed. The spin-dried substrate W is then returned by the transport robot 16 through the loading/unloading station 14 back into the transport box 10.

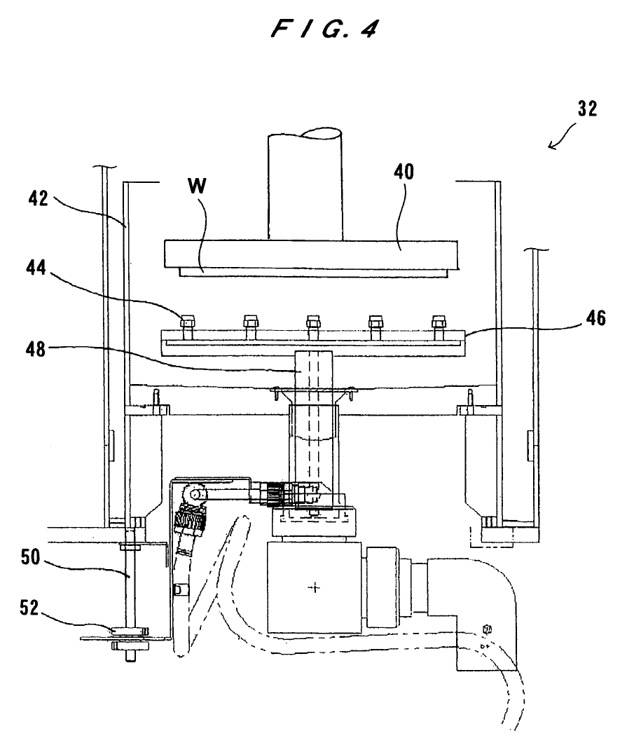

FIG. 4 shows one example of a damaged layer restoring unit 32. As shown in FIG. 4, the damaged layer restoring unit 32 comprises a substrate holder 40 which is rotatable and vertically movable for detachably holding the substrate W with its surface facing downwardly, and a substantially cylindrical processing tank 42. A plurality of liquid ejection nozzles 44 for ejecting a liquid upwardly are mounted on a nozzle plate 46 disposed above the bottom of the processing tank 42. The nozzle plate 46 is mounted on the upper end of a nozzle lifting/lowering shaft 48. The nozzle lifting/lowering shaft 48 is vertically movable by changing the position at which a nozzle position adjusting screw 50 engages with a nut 52 for adjusting the distance between the liquid ejection nozzles 44 and the substrate W positioned thereabove to an optimum value.

In the damaged layer restoring unit 32, the substrate holder 40 which holds the substrate W with its surface facing downwardly is placed in a predetermined position in the processing tank 42. While the substrate holder 40 is rotating, a liquid is ejected from the liquid ejection nozzles 44 toward the substrate W to restore the damaged layers on the surface of the substrate W.

The liquid ejected from the liquid ejection nozzles 44 toward the substrate W may comprise a chemical liquid for dissolving the damaged layer away. Specifically, the damaged layers that are formed on the exposed surfaces of the interconnects 8 in the flattening process include a mixture of a layer that is chemically damaged by the oxidizing agent and a layer that is physically damaged by the polishing agent. In either case, these damaged layers are bonded more weakly to the substrate W than the bulk metal. Therefore, the rates at which the metal (interconnect) and the oxide (damaged layer) are dissolved by chemical liquids are compared with each other, and a chemical liquid for dissolving the damaged layer faster than the interconnect is selected and applied to the surface of the substrate W to remove only the damaged layer which is chiefly composed of the oxide layer without causing damage to the interconnect. If the interconnect is composed of copper or a copper alloy, then the desired effect can be achieved by using as a chemical liquid a non-oxide acid such as hydrochloric acid, sulfuric acid, hydrofluoric acid, or the like.

Since the interconnect may possibly be oxidized by dissolved oxygen in the chemical liquid and portions thereof which are not damaged may possibly be dissolved by the dissolved oxygen in the chemical liquid, the amount of dissolved oxygen in the chemical liquid that is supplied may be reduced and the atmosphere may be controlled to eliminate the effect of oxygen in the atmosphere. The amount of dissolved oxygen in the chemical liquid may be controlled by bubbling the chemical liquid with nitrogen. The atmosphere may be controlled by introducing an inactive gas such as a nitrogen gas during the damage restoring process.

The chemical liquid may be supplied to the surface of the substrate W as by dipping the substrate in the chemical liquid, supplying the chemical liquid to the surface (upper surface) of the substrate W while the substrate W is being held with its surface facing upwardly, or spraying the chemical liquid to the surface (lower surface) of the substrate W while the substrate W is being held with its surface facing downwardly. As described above, portions of interconnects which are not damaged may possibly be dissolved by the oxygen in the atmosphere, depending on the chemical liquid used to dissolve the damaged layer. In this case, the chemical liquid needs to be removed from the surface of the substrate W immediately after the damage restoring process. The substrate W can be rinsed more easily and the supplied chemical liquid can be removed with greater ease in the process of spraying the chemical liquid to the surface (lower surface) of the substrate W while the substrate W is being held with its surface facing downwardly, than the process of dipping the substrate in the chemical liquid or the process of supplying the chemical liquid to the surface (upper surface) of the substrate W while the substrate W is being held with its surface facing upwardly. Alternatively, the environment in which the spray is applied to the substrate W and/or the environment in which the substrate W is rinsed may be filled with an inactive gas to eliminate the effect of the oxygen in the atmosphere during the damage restoring process.

If a process subsequent to the restoration of the damaged layers is an electroless plating process for forming a protective film while the substrate W is being held with its surface facing downwardly, then the damaged layers is restored while the substrate W is being held with its surface facing downwardly. In this manner, the protective layer can subsequently be formed on the substrate W by electroless plating without changing the orientation of the substrate W.

The liquid ejected from the liquid ejection nozzles 44 toward the substrate W may comprise a liquid containing a reducing agent to reduce and restore the damaged layer. Specifically, if the damaged layer is primarily damaged chemically by an oxidizing agent or the like, then it is more appropriate to reduce the damaged layer into a metal state with a reducing agent than to dissolve the damaged layer away. The reducing agent needs to be a substance capable of donating electrons to at least the interconnect material. If the interconnect material is copper, for example, then the reducing agent may be formaldehyde, dimethylamineborane, hydrazine, or the like.

FIG. 5 shows another example of a damaged layer recovering unit 32 that can be used in the semiconductor device manufacturing apparatus. The damaged layer recovering unit 32 shown in FIG. 5 is essentially the same as a CMP unit for performing the CMP process. The damaged layer recovering unit 32 comprises a polishing table 62 having a polishing pad (polishing cloth) 60 applied to its upper surface to provide a polishing surface, and a top ring 64 disposed above the polishing table 62 and rotatable and vertically movable for detachably holding the substrate W with its surface facing downwardly. The polishing table 62 and the top ring 64 are rotatable about their own axes with respect to each other. The damaged layer recovering unit 32 also has a liquid supply nozzle 66 disposed above the polishing table 62. In operation, the polishing table 62 and the top ring 64 are rotated about their own axes, while a liquid containing at least a reducing agent is being supplied from the liquid supply nozzle 66 to the polishing pad 60. The substrate W is pressed against the polishing pad 60 by the top ring 64 to reduce the damaged layer with the reducing agent, as described above, thereby restoring the damaged layer, and to polish the surface of the substrate W simultaneously. The polishing pad 60 may alternatively comprise fixed abrasive grain.

When the damaged layer is continuously restored by the damaged layer restoring unit 32, the polishing capability of the polishing surface of the polishing pad 60 is lowered. In order to recover the polishing capability, a dresser 68 for dressing the polishing pad 60 is provided. When the substrate whose damaged layers are restored is replaced, the dressing of the polishing pad 60 may be carried out with the dresser 68. In the dressing process, the dressing surface (dressing member) of the dresser 68 is pressed against the polishing pad 60 on the polishing table 62, and the dresser 68 and the polishing table 62 are rotated about their own axes with respect to each other to remove an abrasive solution and scraped fragments adhering to the polishing surface, flatten and dress the polishing surface, thereby regenerating the polishing surface.

In this manner, when the chemically damaged layers are restored by the reducing agent, the surface of the substrate W is also polished to uniformly process the entire surface of the substrate W.

If the chemically damaged layer is also slightly physically damaged, then a liquid comprising a reducing agent and abrasive gain (slurry) is supplied from the liquid supply nozzle 66 to the polishing table 62 while polishing thereby restoring the damaged layer which is both chemically and physically damaged.

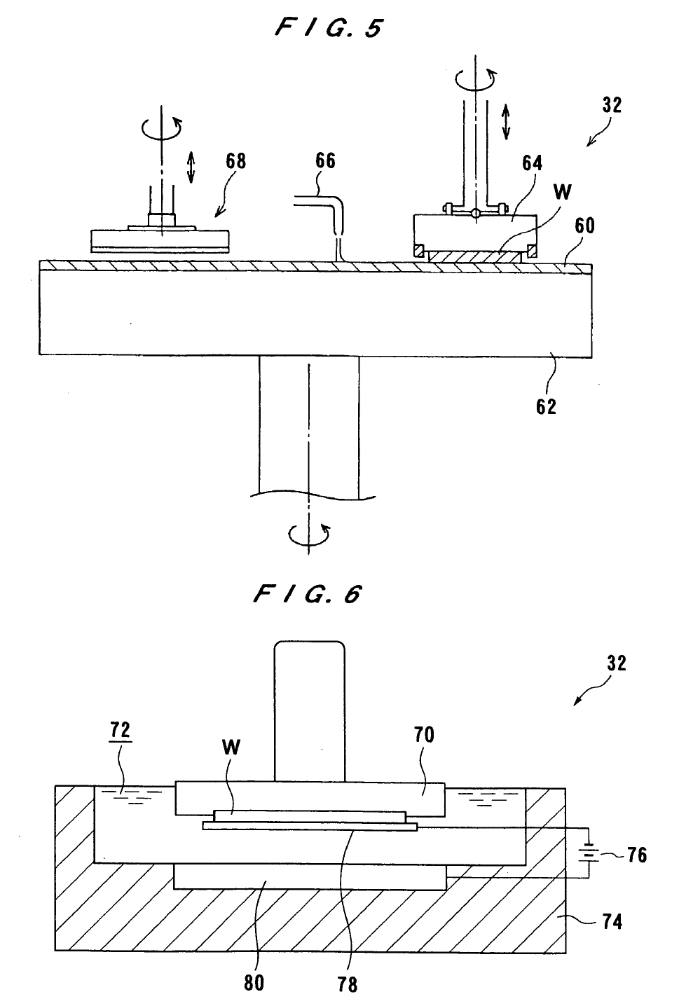

FIG. 6 shows still another example of a damaged layer recovering unit 32 which is capable of restoring the damaged layers formed (remaining) on the surfaces of the interconnects 8 by an electrochemical reducing action. As shown in FIG. 6, the damaged layer recovering unit 32 comprises a substrate holder 70 which is rotatable and vertically movable for detachably holding the substrate W with its surface facing downwardly, and a processing tank 74 disposed below the substrate holder 70 and storing a liquid 72 such as pure water or the like therein. The substrate holder 70 has a mesh-like cathode 78 connected to the cathode electrode of a power source 76, the mesh-like cathode 78 being vertically movable or openable and closable. With the cathode 78 lowered with respect to the substrate holder 70 or the cathode 78 being open, the substrate holder 70 holds the substrate W. Then, the substrate holder 70 is lifted with respect to the substrate holder 70 or the cathode 78 is closed to bring interconnects 8 on the substrate W into contact with the cathode 78 for cathode polarization. A plate-like anode 80 connected to the anode electrode of the power source 76 is mounted on the bottom of the processing tank 80.

In operation, the substrate holder 70 holds the substrate W with interconnects 8 held in contact with the cathode 78. The substrate holder 70 is lowered to dip the substrate W in a liquid such as pure water or the like stored in the processing tank 74. Then, the cathode electrode of the power source 76 is connected to the cathode 78, and the anode electrode of the power source 76 is connected to the anode 80. Interconnects 8 formed on the surface of the substrate W undergoes anode polarization, thus electrochemically reducing the damaged layers to restore the damaged layers.

As described above, if the damaged layer is reduced into a metal state by a reducing solution, then the substrate W needs to be rinsed subsequently. However, interconnects 8 may possibly be damaged while the substrate W is being rinsed. In the present embodiment, since the damaged layer (oxide layer) is restored by an electrochemical reducing action by subjecting the interconnects 8 on the surface of the substrate W to cathode polarization in ultrapure water or the like, the substrate W does not need to be rinsed, and hence is not damaged in the rinsing process. If the interconnect material is copper, then the damaged layer (oxide layer) immediately after it is produced can be reduced to copper when subjected to cathode polarization at a potential of about 0.4 V with respect to the standard hydrogen electrode potential.

The embedded interconnects 8 formed on the surface of the substrate may be subjected to cathode polarization most easily by bringing the mesh-like cathode 78 into contact with the surface of the substrate W. Even if a hydrogen gas is generated, the cathode 78 which is of a mesh structure allows the hydrogen gas to be easily removed, making it possible to perform the reducing reaction smoothly. The electrode material is preferably a material having a high hydrogen overvoltage, such as copper, lead, zinc, or the like in order that the cathode current will not be used to generate hydrogen.

According to the present embodiment, as described above, the damaged layer which is necessarily produced on the exposed surface of interconnect by the flattening for forming interconnect according to the damascene process is restored, and interconnect with the restored damaged layer is processed in a next process. Therefore, the adverse effect which the damaged layer would have if left on the surface of interconnect is eliminated, allowing semiconductor devices to be manufactured with a high yield.

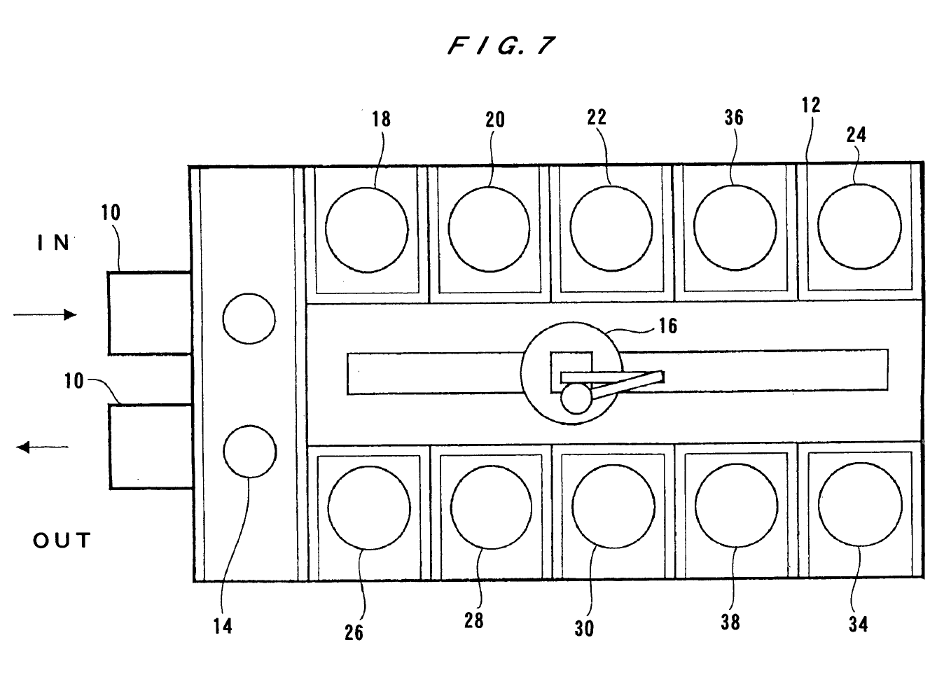

FIG. 7 shows in plan a semiconductor device manufacturing apparatus according to another embodiment of the present invention. As with the semiconductor device manufacturing apparatus shown in FIG. 2, the semiconductor device manufacturing apparatus shown in FIG. 7 has a rectangular housing 12 to which transport boxes 10 are detachably mounted. The housing 12 houses therein a loading/unloading station 14, a transport robot 16, an electroplating unit 18 as a film deposition unit for embedding, a cleaning/drying unit 20, a bevel etching/reverse side cleaning unit 22, a film thickness measuring unit 24, a heat-treating (annealing) unit 26, a pretreatment unit 28, an electroless plating unit 30 (cap plating unit) for forming a protective film, and a polishing unit 34. In the present embodiment, the housing 12 also houses therein an etching unit 36 and a restoring unit 38.

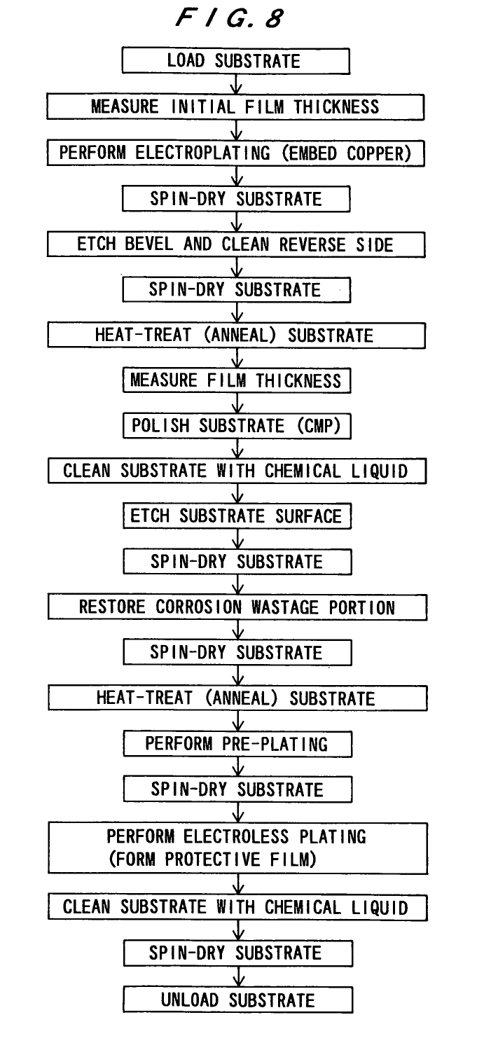

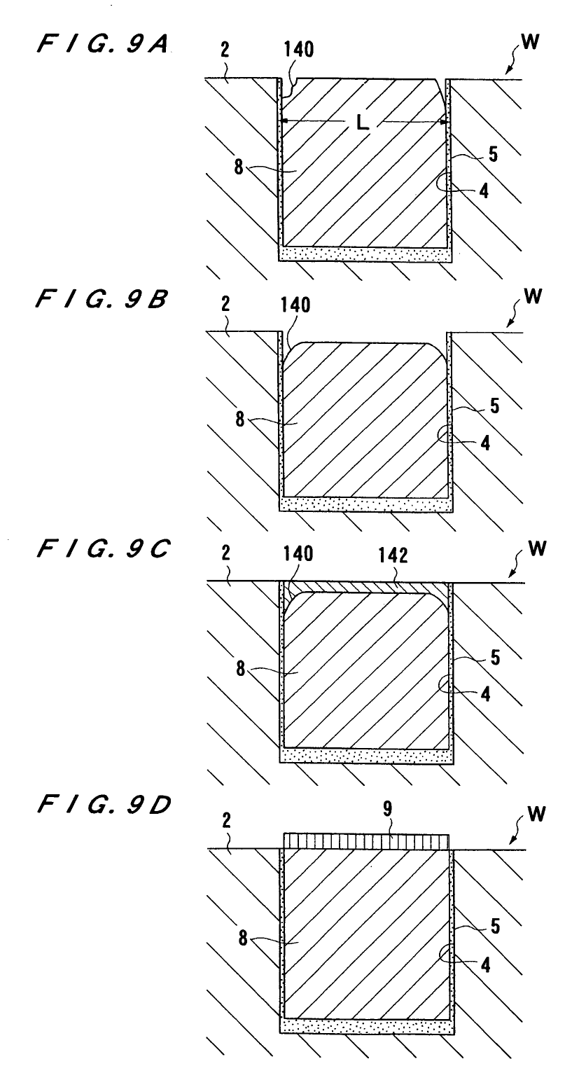

A successive step of a process of forming copper interconnects on a substrate W with a seed layer 6 formed on its surface shown in FIGS. 1A through 1D, using the semiconductor device manufacturing apparatus shown in FIG. 7, will be described below with reference to FIGS. 8 and 9A through 9D.

As with above-described embodiment, a substrate W with a seed layer 6 formed on its surface is taken one by one from one of the transport boxes 10 into the loading/unloading station 14. An initial film thickness, i.e., the film thickness of the seed layer 6, is measured, copper is embedded, the substrate is spin-dried, the bevel is etched and the reverse side cleaned, the substrate is spin-dried, the substrate is heat-treated (annealed), the copper film thickness is measured, the substrate is polished by CMP, the substrate is cleaned by a chemical liquid (post-cleaning), and the substrate is cleaned (rinsed) and dried.

When the surface of the substrate W is polished into a flat surface by chemical mechanical polishing or the like and then post-cleaned, if the substrate W is brought into a state where the copper as the interconnect material and the barrier material coexist on the surface of the substrate W, then the portions of the copper interconnects which have boundaries held in contact with the barrier material are corroded due to a potential difference that is developed between the copper and the barrier material during the polishing process or post-cleaning process, tending to produce a local corrosion wastage portion (spike) 140 in the interface between the barrier material and the copper interconnect 8, as shown in FIG. 9A. The corrosion wastage portion 140 in the copper interconnect 8 is responsible for a reduction in the reliability of the semiconductor device due to an increase in the interconnect resistance, poor adhesion between the interconnect material and a film formed thereon, etc.

As the polishing process has been improved to reduce excessive polishing in view of finer design rules, e.g., a semiconductor device generation where the interconnect trench (interconnect recess) 4 in the insulating film (interlevel dielectric) 2 has a width L smaller than 0.1 μm, the corrosion wastage that has been concealed has begun to surface, tending to affect the reliability of semiconductor devices. When a protective film (cap) composed of a metal having a high melting point is selectively deposited by electroless plating on the surfaces of interconnects to protect the interconnects, the corrosion wastage may further be promoted depending on processing conditions of the electroless plating process.

In the present embodiment, the corrosion wastage portions 140 on the surface of the copper interconnects 8 are restored. Specifically, the substrate W that is post-cleaned after being flattening is transported by the transport robot to the etching unit 36, which etches the surface of the substrate W to make blunt the shape of the corrosion wastage portion 140, as shown in FIG. 9B. Specifically, before the corrosion wastage portion 140 is restored, at least a surrounding region of the corrosion wastage portion 140 of the copper interconnect 8 is etched away to make blunt the shape of the corrosion wastage portion 140. The corrosion wastage portion 140 thus made blunt in shape allows itself to be restored with ease. This etching process may be performed optionally.

Thereafter, the etched substrate W is transported by the transport robot 16 to the cleaning/drying unit 20, which cleans the substrate W with pure water and then spin-dries the substrate W. If the etching unit 36 has a spin-drying function, then the etching unit 36 spin-dries the substrate W. The dried substrate W is transported to the restoring unit 38 by the transport robot 16.

The restoring unit 38 of this embodiment comprises an electroless plating unit. The restoring unit (electroless plating unit) 38 performs electroless copper plating on the surfaces of interconnects (copper interconnects) 8 to selectively form a restorative film 142 of copper mainly on the corrosion wastage portions 140. The corrosion wastage portions 140 are thus filled up with the restorative film 142, and at the same time the surface of the restorative film 142 is made lying flush with the surface of the substrate W, thereby restoring the corrosion wastage portions 140.

At this time, the surfaces of interconnects 8 other than the corrosion wastage portions 140 may be rubbed by the polishing cloth during the electroless plating process, suppressing the precipitation of a plated film in regions other than the regions to be restored for better selectivity.

In the present embodiment, the restoring unit 38 comprises an electroless plating unit. However, the restoring unit 38 may comprise an electroplating unit. If the restoring unit 38 comprises an electroplating unit, then an additive for good embeddability of the plating solution may be selected to precipitate the interconnect material from the corrosion wastage portions to restore the corrosion wastage portions. The electroplating needs to subject the interconnects to cathode polarization, and contacts may be provided on pad regions on respective chips on the substrate to supply an electric current to the interconnects.

A process of restoring the corrosion wastage portions formed on the exposed surfaces of interconnects by a flattening process such as a polishing process or a post-cleaning process needs to deposit the interconnect material mainly in the corrosion wastage portions only. Since the electroless plating or electroplating process can meet such a need, and is a wet process to be performed in a solution, it better matches the polishing process or the post-cleaning process if it follows these processes in the same apparatus.

The substrate W with the corrosion wastage portions 140 thus restored is transported by the transport robot 16 to the cleaning/drying unit 20, which cleans the substrate W with pure water and then spin-dries the substrate W. If the restoring unit 38 has a spin-drying function, then the restoring unit 38 spin-dries (dewaters) the substrate W. The dried substrate W is transported to the heat-treating unit 26 by the transport robot 16.

The heat-treating unit 26 heat-treats (anneals) the substrate W. When the substrate W is heat-treated, the adhesion between the interconnect 8 as an un-restored region and a restorative film 142 as a restored region is improved, and the film quality of the interconnect 8 is increased. This heat-treating process may be performed optionally.

As with above-described embodiment, the heat-treated substrate W is then transported by the transport robot 16 to the pretreatment unit 28, which performs a pre-plating process. The pre-plated substrate W is then spin-dried, and transported to the electroless plating unit 30 (cap plating unit) for forming a protective film by the transport robot 16. The electroless plating unit 30 selectively forms a protective film (cap) 9 composed of a Co—W—P alloy film on the exposed surface of the interconnects 8, thereby protecting the interconnects 8.

Because the corrosion wastage portions 140 are restored and then the protective film (cap) 9 composed of a Co—W—P alloy film is formed on the surfaces of the interconnects 8, the protective film 9 can be formed on the surfaces of interconnects 8 while preventing voids from being formed in the interconnects 8, as shown in FIG. 9D. Thus, the reliability of interconnects 8 is increased, and the resistance thereof is prevented from increasing.

As with above-described embodiment, after the electroless plating process, the substrate W is transported by the transport robot 16 to the cleaning/drying unit 20, which cleans the surface of the substrate W with a chemical liquid, cleans (rinses) the surface of the substrate W with pure water, and thereafter spin-dries the substrates W by rotating the substrate W at a high speed. The spin-dried substrate W is then returned by the transport robot 16 through the loading/unloading station 14 back into the transport box 10.

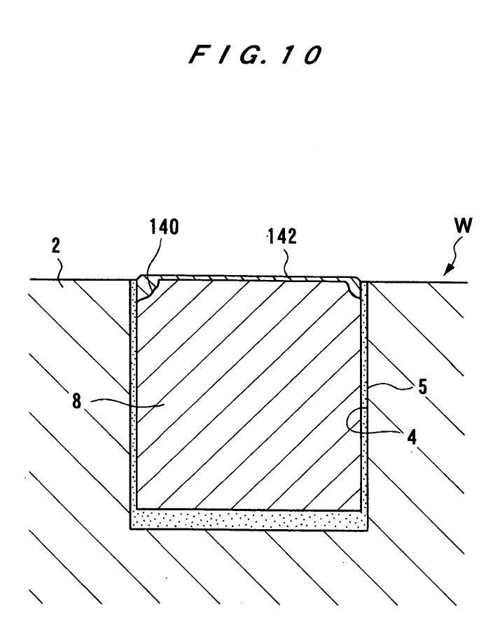

In the above embodiment, the surface of the substrate W is etched to make blunt the shape of the corrosion wastage portion 140 and then the corrosion wastage portion 140 is restored. However, depending on the shape or depth of the corrosion wastage portion 140, as shown in FIG. 10, the surface of the substrate W may not be etched, but the corrosion wastage portion 140 may remain as it is, and a (copper) restorative film 142 may be formed on the surface of the (copper) interconnects 8 to restore the corrosion wastage portion 140.

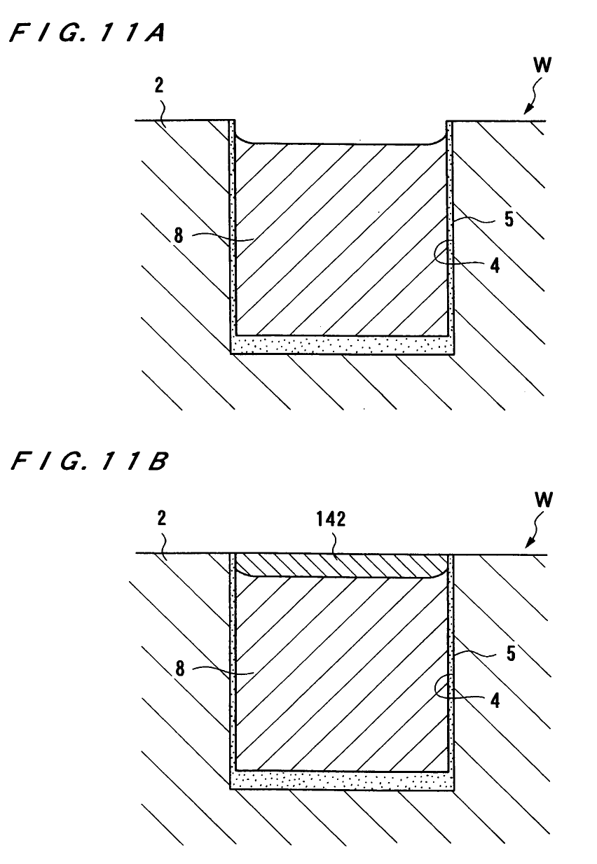

Alternatively, as shown in FIG. 11A, the surface of the substrate W may be etched to make concave the surface of each interconnect 8, i.e., at a rate greater in the central regions of the interconnects 8 than in the outer peripheral regions thereof. Then, as shown in FIG. 11B, a restorative film 142 may be formed on the surfaces of interconnects 8 to restore the corrosion wastage portions 140. In this manner, the reliability of the restoration of the corrosion wastage portions can be increased.

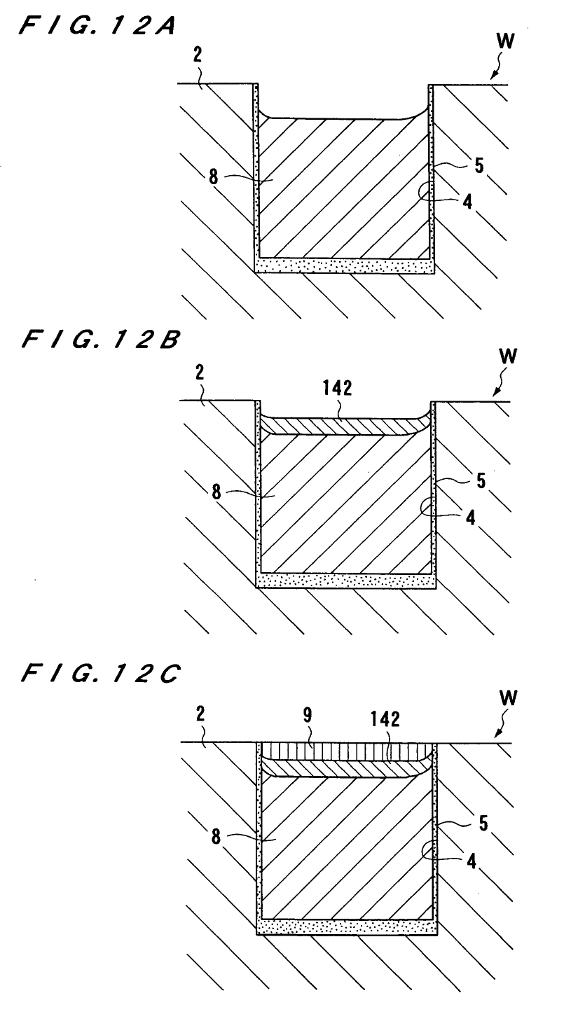

Alternatively, as shown in FIG. 12A, the surface of each interconnect 8 may be etched to a depth commensurate with the sum of the film thickness of the restorative film 142 and the film thickness of the protective film 9. Then, as shown in FIG. 12B, the restorative film 142 is formed on the surfaces of interconnects 8 to restore the corrosion wastage portions. Thereafter, as shown in FIG. 12C, the protective film 9 may be formed on the surface of the restorative film 142 until the surface of the protective film 9 lies flush with the surface of the insulating film (interlevel dielectric) 2. By making the surface of the protective film 9 lying flush with the surface of the interlevel dielectric 2 thereby flattening the surface of the substrate W, it is possible to perform easily a subsequent process of forming an insulating film, and forming vias and trenches through application of a resist layer and exposure to light, and the like.

In the above embodiment, the interconnect material comprises copper. However, the interconnect material may be copper alloy, silver, silver alloy, tungsten, tungsten alloy, or the like.

According to the above embodiment, as described above in detail, since the corrosion wastage portion formed on the exposed surface of the interconnect by the flattening process for forming the interconnect according to the damascene process is restored, and the substrate with the corrosion wastage portion being restored is processed in a next process. Therefore, embedded interconnects less liable to suffer defects are formed, allowing highly reliable semiconductor devices to be manufactured.

Although certain preferred embodiments of the present invention have been shown and described in detail, it should be understood that various changes and modifications may be made therein without departing from the scope of the appended claims.

What is claimed is:

1. A method of manufacturing a semiconductor device, comprising:
preparing a substrate having a interconnect recess formed in an interlevel dielectric on a surface of the substrate;
depositing an interconnect material on the surface of the substrate to embed the interconnect material in the interconnect recess;
removing the interconnect material excessively formed on the surface of the substrate to flatten the surface of the substrate, thereby forming an interconnect of said interconnect material; and
restoring a damaged layer formed on the exposed surface of said interconnect.

2. A method according to claim 1, wherein said damaged layer is restored by a dry process.

3. A method according to claim 1, wherein said damaged layer is restored by a wet process.

4. A method according to claim 3, wherein said damaged layer is restored by the wet process, following said removing the interconnect material excessively formed on the surface of the substrate to flatten the surface of the substrate.

5. A method according to claim 3, wherein said damaged layer is restored by the wet process, following said removing the interconnect material excessively formed on the surface of the substrate to flatten the surface of the substrate and drying the substrate.

6. A method according to claim 3, wherein said damaged layer is dissolved away in a chemical liquid.

7. A method according to claim 6, wherein said chemical liquid is ejected to the surface of said substrate that is held with the surface facing downwardly.

8. A method according to claim 3, wherein said damaged layer is restored by being reduced with a solution containing a reducing agent.

9. A method according to claim 8, wherein said solution containing the reducing agent is ejected to the surface of said substrate that is held with the surface facing downwardly.

10. A method according to claim 3, wherein the surface of the substrate is polished in the presence of a solution containing a reducing agent.

11. A method according to claim 10, wherein the surface of the substrate is polished by moving the substrate and a polishing surface relatively to each other while pressing the surface of said substrate that is held with the surface facing downwardly against said polishing surface.

12. A method according to claim 3, wherein the surface of the substrate is polished using a slurry containing at least a reducing agent and abrasive grain.

13. A method according to claim 12, wherein the surface of the substrate is polished by moving the substrate and a polishing surface relatively to each other while pressing the surface of said substrate that is held with the surface facing downwardly against said polishing surface.

14. A method according to claim 3, wherein the interconnect formed on the surface of the substrate is subjected to cathode polarization, and said damaged layer is restored by being reduced electrochemically.

15. A method according to claim 14, wherein a mesh-like cathode is held in contact with the surface of the substrate to subject the interconnect to cathode polarization.

16. A method according to claim 1, wherein said interconnect material comprises copper, a copper alloy, silver, or a silver alloy.

17. A method according to claim 1, wherein said interconnect material is deposited by plating.

18. A method according to claim 1, wherein said removing the interconnect material excessively formed on the surface of the substrate to flatten the surface of the substrate is performed by chemical mechanical polishing, electrochemical polishing, composite electrolytic polishing, or a combination thereof.

19. A method according to claim 1, wherein said damaged layer is restored in a light-shielded environment.

20. A method according to claim 1, further comprising:
selectively forming a protective film on the exposed surface of the interconnect in the surface of the substrate after the damaged layer is restored.

21. A method according to claim 20, wherein said protective film is formed by electroless plating, and the substrate is dried after said protective film is formed by electroless plating.

22. An apparatus for manufacturing a semiconductor device, comprising:
a plating unit for depositing an interconnect material on a surface of a substrate having an interconnect recess formed in an interlevel dielectric to embed the interconnect material in the interconnect recess;
a polishing unit for removing the interconnect material excessively formed on the surface of the substrate to flatten the surface of the substrate, thereby forming an interconnect of said interconnect material; and
a damaged layer restoring unit for restoring a damaged layer formed on the exposed surface of said interconnect.

23. An apparatus according to claim 22, wherein said damaged layer restoring unit comprises:
a substrate holder for holding the substrate with the surface facing downwardly; and
a liquid ejection nozzle for ejecting a liquid toward the surface of the substrate that is held by said substrate holder.

24. An apparatus according to claim 23, wherein said liquid comprises a chemical liquid for dissolving said damaged layer or a solution containing a reducing agent.

25. An apparatus according to claim 22, wherein said damaged layer restoring unit comprises:
a top ring vertically movable for holding the substrate with the surface facing downwardly;
a polishing table having an upper surface as a polishing surface;
a liquid supply nozzle for supplying a liquid to the polishing surface of said polishing table; and
a relatively moving mechanism for moving said top ring and said polishing table relatively to each other.

26. An apparatus according to claim 25, wherein said liquid comprises a solution containing a reducing agent or a slurry containing a reducing agent and abrasive grain.

27. An apparatus according to claim 22, wherein said damaged layer restoring unit comprises:
a mesh-like cathode for contacting the surface of the substrate to subject said interconnect to cathode polarization;
an anode disposed in confronting relation to the surface of the substrate; and
a liquid filled between said surface of the substrate and said anode.

28. An apparatus according to claim 22, further comprising:
an electroless plating unit for selectively forming a protective film on the exposed surface of said interconnect.

29. A method of manufacturing a semiconductor device, comprising:
preparing a substrate having an interconnect recess formed in an interlevel dielectric on a surface of the substrate;
depositing an interconnect material on the surface of the substrate to embed the interconnect material in the interconnect recess;
removing the interconnect material excessively formed on the surface of the substrate to flatten the surface of the substrate, thereby forming an interconnect of said interconnect material; and
restoring a wastage portion formed on the exposed surface of the interconnect when the surface of the substrate has been flattened.

30. A method according to claim 29, wherein said interconnect recess has a minimum dimension of up to 0.1 μm.

31. A method according to claim 29, wherein said wastage portion formed on the exposed surface of the interconnect is restored by electroless plating or electroplating.

32. A method according to claim 29, further comprising:
etching away at least a portion of a peripheral region of the exposed surface of the interconnect before said wastage portion is restored.

33. A method according to claim 29, further comprising:
heat-treating the substrate after said wastage portion is restored.

34. A method according to claim 29, wherein said interconnect material is deposited by sputtering, CVD, plating, or a combination thereof.

35. A method according to claim 29, wherein said interconnect material is deposited by a process including a plating process having at least two plating conditions changed.

36. A method according to claim 29, wherein said interconnect material comprises aluminum, copper, or silver, or an alloy thereof.

37. A method according to claim 29, wherein said surface of the substrate is flattened by chemical mechanical polishing, composite electrolytic polishing, electrolytic polishing, or a combination thereof.

38. A method according to claim 29, further comprising:
selectively forming a protective film on the exposed surface of the interconnect by electroless plating, after the wastage portion formed on the exposed surface of the interconnect is restored.

39. A method according to claim 38, wherein said protective film is formed so as to have a surface thereof lying flush with a surface of said interlevel dielectric.

40. An apparatus for manufacturing a semiconductor device, comprising:
a film deposition unit for depositing an interconnect material on a surface of a substrate having an interconnect recess formed in an interlevel dielectric to embed the interconnect material in the interconnect recess;
a polishing unit for removing the interconnect material excessively formed on the surface of the substrate to flatten the surface of the substrate, thereby forming an interconnect of said interconnect material; and
a restoring unit for restoring a wastage portion formed on the exposed surface of the interconnect when the surface of the substrate has been flattened by said polishing unit.

41. An apparatus according to claim 40, wherein said film deposition unit comprises an electroplating unit, an electroless plating unit, or a combination thereof.

42. An apparatus according to claim 40, wherein said restoring unit comprises an electroplating unit or an electroless plating unit.

43. An apparatus according to claim 40, further comprising:
an electroless plating unit for selectively forming a protective film on the exposed surface of the interconnect which is restored by said restoring unit.

44. An apparatus according to claim 40, further comprising:
an etching unit for etching away at least a portion of a peripheral region of the exposed surface of the interconnect before said wastage portion is restored by said restoring unit.

45. An apparatus according to claim 40, further comprising:
a heat-treating unit for heat-treating the substrate in which the wastage portion has been restored by said restoring unit.
